(19) United States
(12) Patent Application Publication
(10) Pub. No.: US 2015/0262814 A1
(43) Pub. Date: Sep. 17, 2015

(54) POWER SEMICONDUCTOR DEVICE,POWER ELECTRONIC MODULE, AND METHOD FOR PROCESSING A POWER SEMICONDUCTOR DEVICE

(71) Applicant: Infineon Technologies AG, Neubiberg (DE)

(72) Inventors: Mathias Plappert, Villach (AT); Eric Graetz, Krumpendorf (AT); Andreas Behrendt, Villach (AT); Oliver Humbel, Maria Elend (AT); Carsten Schaeffer, Annenheim (AT); Angelika Koprowski, Klagenfurt (AT)

(73) Assignee: Infineon Technologies AG, Neubiberg (DE)

(21) Appl. No.: 14/207,685

(22) Filed: Mar. 13, 2014

(51) Int. Cl. H01L 21/02; H01L 21/311; H01L 23/31; H01L 23/29; H01L 29/06; H01L 29/40

(52) U.S. Cl. CPC H01L 21/02126; H01L 29/0619; H01L 29/402; H01L 21/022; H01L 21/02282; H01L 21/02288; H01L 21/02318; H01L 23/3171; H01L 23/296; H01L 21/31133

(57) ABSTRACT

A power semiconductor device in accordance with various embodiments may include: a semiconductor body; and a passivation layer disposed over at least a portion of the semiconductor body, wherein the passivation layer includes an organic dielectric material having a water uptake of less than or equal to 0.5 wt % in saturation.

### TECHNICAL FIELD

Various embodiments relate to a power semiconductor device, a power electronic module, and a method for processing a power semiconductor device.

### BACKGROUND

Power semiconductor devices such as power transistors (e.g. insulated-gate bipolar transistors, IGBTs) or diodes may be implemented in power electronic modules. Sometimes, power devices or modules may need to be operated under harsh environmental conditions such as, e.g., heat, humidity, or air pollution, which may affect performance or even lead to failure of the devices or modules. Thus, it may be desirable to improve reliability of the devices or modules under harsh environmental conditions.

### SUMMARY

In accordance with various embodiments, a power semiconductor device may include: a semiconductor body; a passivation layer disposed over at least a portion of the semiconductor body, wherein the passivation layer includes an organic dielectric material having a water uptake of less than or equal to 0.5 wt % in saturation.

In accordance with various embodiments, a power electronic module may include: a plurality of power semiconductor devices, each including a semiconductor body and a passivation layer disposed over at least a portion of the semiconductor body, wherein the passivation layer includes an organic dielectric material having a water uptake of less than or equal to 0.5 wt % in saturation; and at least one contact connected to the plurality of power semiconductor devices.

In accordance with various embodiments, a method for processing a power semiconductor device may include: depositing a thermally curable silicone material over a semiconductor body of a power semiconductor device; and thermally curing the thermally curable silicone material in an inert atmosphere having an oxygen level of less than or equal to 1 ppm.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 and FIG. 2 show various views illustrating corrosion at field plates of a field plate structure in a conventional power semiconductor device that was subjected to high-voltage long-term testing under high humidity and temperature;

FIG. 3 shows a view of chips of a power module that were passivated by a passivation layer in accordance with an embodiment during the long-term testing;

FIG. 4 shows a semiconductor device in accordance with various embodiments;

FIG. 5 shows another semiconductor device in accordance with various embodiments;

FIG. 6 shows a power electronic module in accordance with various embodiments; and

FIG. 7 shows a method for for processing a power semiconductor device in accordance with various embodiments.

### DESCRIPTION

The following detailed description refers to the accompanying drawings that show, by way of illustration, specific details and embodiments in which the invention may be practised. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments. Various embodiments are described in connection with methods and various embodiments are described in connection with devices. However, it may be understood that embodiments described in connection with methods may similarly apply to the devices, and vice versa.

The word “exemplary” is used herein to mean “serving as an example, instance, or illustration”. Any embodiment or design described herein as “exemplary” is not necessarily to be construed as preferred or advantageous over other embodiments or designs.

The terms “at least one” and “one or more” may be understood to include any integer number greater than or equal to one, i.e. one, two, three, four, . . . , etc.

The term “a plurality” may be understood to include any integer number greater than or equal to two, i.e. two, three, four, five, . . . , etc.

The word “over”, used herein to describe forming a feature, e.g. a layer “over” a side or surface, may be used to mean that the feature, e.g. the layer, may be formed “directly on”, e.g. in direct contact with, the implied side or surface. The word “over”, used herein to describe forming a feature, e.g. a layer “over” a side or surface, may be used to mean that the feature, e.g. the layer, may be formed “indirectly on” the implied side or surface with one or more additional layers being arranged between the implied side or surface and the formed layer.

In like manner, the word “cover”, used herein to describe a feature disposed over another, e.g. a layer “covering” a side or surface, may be used to mean that the feature, e.g. the layer, may be disposed over, and in direct contact with, the implied side or surface. The word “cover”, used herein to describe a feature disposed over another, e.g. a layer “covering” a side or surface, may be used to mean that the feature, e.g. the layer, may be disposed over, and in indirect contact with, the implied side or surface with one or more additional layers being arranged between the implied side or surface and the covering layer.

The terms “coupling” or “connection” may be understood to include both the case of a direct “coupling” or “connection” and the case of an indirect “coupling” or “connection”.

For the following description the application of a power semiconductor device such as, e.g., a power transistor (e.g., an IGBT power transistor) or a power diode in the application “traction” (e.g. railway technology) will be used as an example in various places. This application is characterized by extremely harsh conditions with respect to temperature/air humidity and life time (>20 years). The typically known error in this case is corrosion, which may be avoided by the passivation scheme described herein. However, corrosion is only an example.

The scheme described herein may be suited for all semiconductor systems to be used under extreme environmental stress (e.g. also chemical impacts).

High-voltage power semiconductor devices or components may need a suitable high-voltage boundary termination in order to have blocking capability. Various constructions such as, e.g., field plate constructions, p guard ring constructions, sometimes also combined with field plates and also VLD (variation of lateral doping) concepts, may be employed in this context. An important element of these constructions may be a passivation layer, which may also consist of several layers, as the case may be. This passivation layer may serve to protect the component against penetration of moisture and ionic contaminations during operation. On chip level, imides are conventionally used as final terminating protection layer in high-voltage components.

Penetration of moisture into the boundary area of the chip may lead to changes in the blocking capability of the chip. Corrosion problems are oftentimes observed at the metal plates and further boundary concepts in very aggressive and extensive long-term testing under humidity (e.g., in a High Voltage (HV) H3TRB test, i.e. a test based on the so-called H3TRB (High Humidity High Temperature Reverse Bias) test defined in international standard TEC 60749, but without the voltage limit of the H3TRB test). Typically, those metal plates consist of aluminum or aluminum alloys (e.g. aluminum with addition of Cu and/or Si, i.e. AlSi, AlSiCu, AlCu). In modern technologies, additions of Si and especially Cu are mainly used. Both elements, and particularly Cu, are elements that promote corrosion since they form precipitations that constitute local cells and furthermore disrupt formation of a native aluminum oxide layer. This enables a free electron exchange, which is required for the redox reaction of aluminum corrosion. As a consequence of the volume expansion (formation of aluminum hydroxide Al(OH)₃) the corrosions at the metal field plates or other metal contacts may lead to further destruction of the passivation and loss of the blocking capability of the high-voltage boundary construction.

Furthermore, the moisture input into the passivation system during the long term stress tests may lead to an oxidation of the passivating layers (e.g. nitride, diamond like carbon (DLC)).

The aforementioned passivation (in high-voltage devices typically photopatternable polyimide) needs to be moisture proof in order to prevent these corrosion occurrences or oxidation of the passivating layers. To begin with, stability against moisture is characterized by low binding of environmental moisture in a material (mostly in form of water vapor from the air humidity), also known as and in the following described as deliquescence. When water/moisture uptake of a passivation is large, this may lead to corrosion as described above.

In addition, adhesion of the passivation may be an important criterion. In case delaminations occur due to non-adjusted mechanical stress, a moisture film may develop between passivation and metal/insulator, which in turn may accelerate the aforementioned corrosion or immediate failure of the high-voltage boundary termination. Sufficient adhesion may require a layer which is free, or substantially free, of mechanical stress. Polyimides currently used may show comparatively high tensile stress in the GPa range.

Adhesion, or stress-free passivation, may not only be important with respect to corrosion. Poor adhesion, or delamination, may accelerate also other environmental impacts (e.g. chemical impacts).

Previously, passivation systems with somewhat improved moisture resistance have been developed. These improved passivation systems achieve enhanced lifetimes so that an H3TRB (High Humidity High Temperature Reverse Bias) test at 80 V blocking voltage may be safely passed.

However, it has turned out that these passivation systems alone may not be sufficient for future moisture robustness requirements. Depending on the application, what may be required for future technologies is blocking stability for >1000 h (more than 1000 hours) in, e.g., an HV H3TRB test. Under these tightened conditions of the H3TRB test, sometimes only life spans of <1000 h may be achieved. Failure analyses of these devices predominantly show corrosion problems at the aluminum metallization in the high-voltage boundary both at the anode side and at the cathode side.

Oftentimes, simple metallizations made of aluminum or an aluminum alloy may be used in power semiconductors at the boundary region which is capable of blocking. Moreover, newer technologies may provide buried VLD implantations, which may replace the typical high-voltage boundaries. Si₃N₄ cap layers or stacked layers of SiO₂ and Si₃N₄ may commonly be used for passivation. These passivations may typically be terminated with a photopatternable polyimide.

This passivation system has proven to be insufficient with respect to the high-voltage H3TRB robustness. Up to now, no passivation system has been presented that is able to safely prevent, for both aluminum in high-voltage boundary terminations and for buried VLD layers including insulator, corrosion processes at the HV boundary.

Reasons for this may be seen in the poor impermeability of the passivation (specifically, of the Si₃N₄ and SiO₂ layers disposed under the imide) at topography steps (growth grooves) or possible defects (pinholes or particles).

However, the basic problem may be seen in that moisture can penetrate through the terminating polyimide layer up to such thin layer defects in the first place.

The insufficient passivation with respect to HV-H3TRB has been detected in a large number of investigations at systems with different passivations of different technologies. Error analyses have repeatedly shown that local corrosion problems at aluminum on the one hand and at the VLD stack on the other hand may lead to failure of the device.

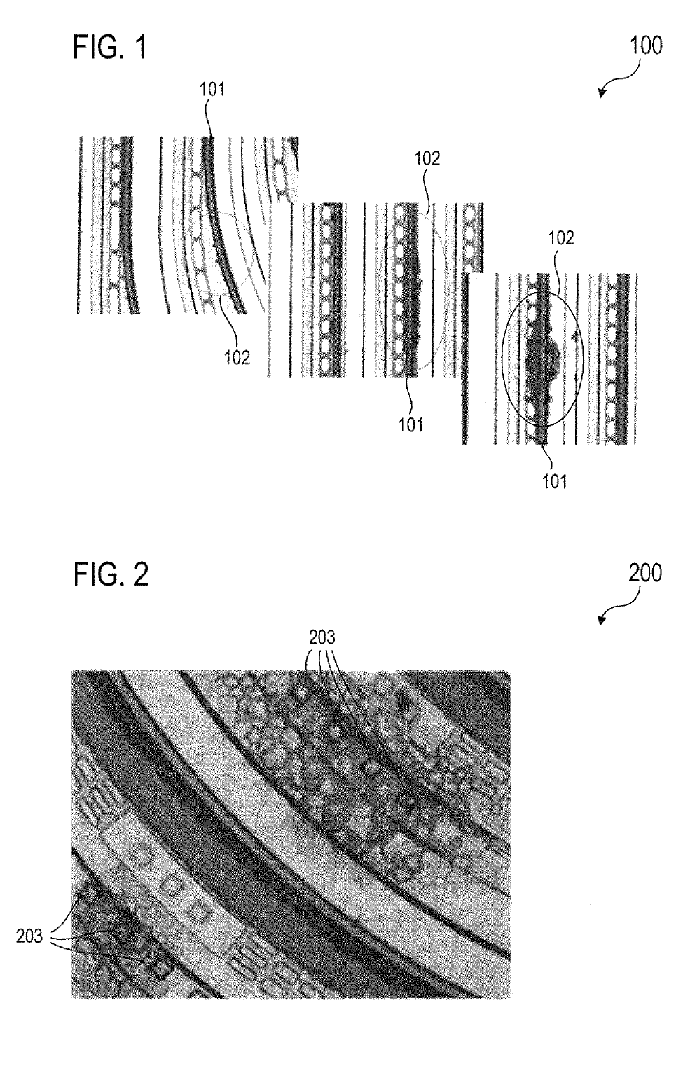

For illustration purposes, FIGS. 1 and 2 show examples of corrosions. It should be noted that at the ends of the field plates locally enhanced field strengths may be present, which may accelerate the electrochemical corrosion process.

FIG. 1 shows, in a view 100, development of corrosion (in regions 102) in a high-voltage H3TRB test at aluminum field plates 101 of a power semiconductor field plate structure.

FIG. 2 shows, in a view 200, onset of corrosion at contacts 203 to polysilicon due to poor edge coverage of the passivation (provoked by a sputtered aluminum layer on deep steep contact hole).

Current passivation systems may be intended to passivate the chips also against other environmental impacts.

In accordance with various embodiments, conventionally used passivations (e.g. polyimide) may be replaced or supplemented with a stress-free and lowly hygroscopic passivation such as, e.g., a silicone passivation. In one or more embodiments, the silicone passivation may include or may be made of spin-coatable silicone (also referred as spin-on silicone, in other words, silicone that may be deposited by means of a spin-coating process (spin-on process)). In one or more embodiments, the silicone passivation may include or may be made of laminatable silicone, in other words, silicone that may be deposited by film lamination. For example, in one or more embodiments, the silicone passivation may include or may be a silicone foil. In one or more embodiments, the silicone passivation may include or may be made of printable silicone, in other words, silicone that may be deposited by a printing process, e.g. stencil printing, screen printing, inkjet printing, or the like.

The new passivation (e.g. silicone, e.g. spin-on silicone) may be implemented in current high-voltage technologies without changing the existing process flow (except an IMID (inter metal isolation dielectric) block).

Experiments on existing power semiconductor technologies with silicone as a replacement for imide showed a significant improvement in the tightened HV-H3TRB test. In particular, five out of five manufactured modules (each having 32 IGBT chips with silicone) exceeded the 1000 h stress limit.

An analyzed module showed no signs of corrosion of the aluminum metallization after 1000 h stress in the HV-H3TRB test. In contrast thereto, modules with polyimide may show signs of corrosion at typical locations before 1000 h in the same test (see, e.g., FIG. 1 and FIG. 2).

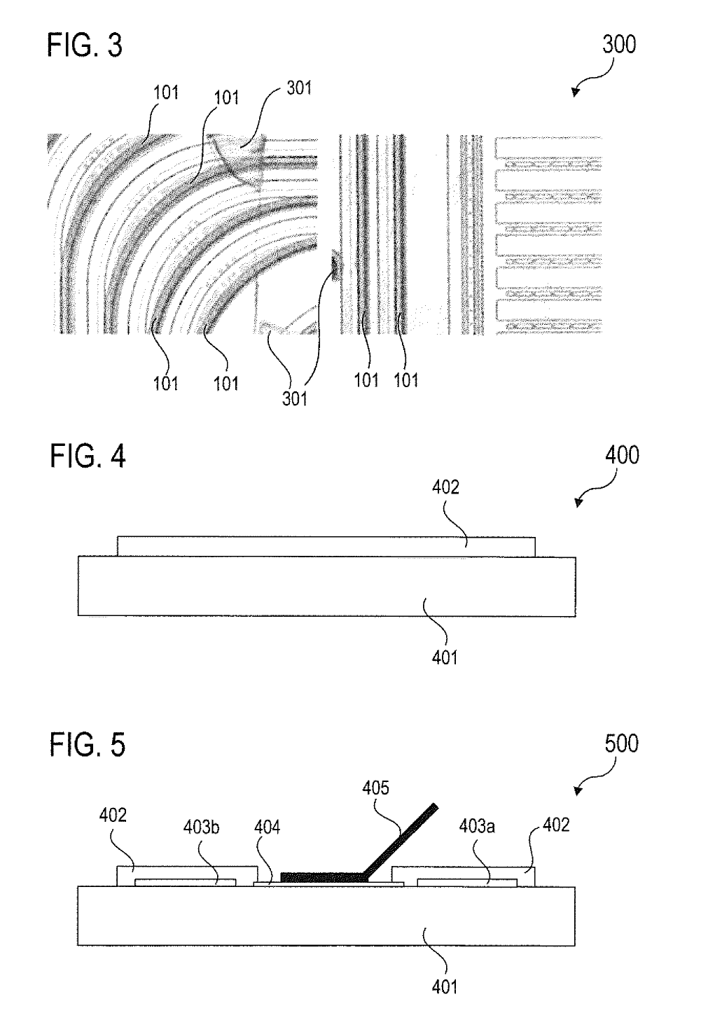

FIG. 3 shows, in a view 300, sections of IGBT chips of a power module that have been passivated with a layer of spin-on silicone in accordance with an embodiment. The chips are completely free of corrosion. This holds true even for typical locations which may be prone to corrosion due to the construction. For example, view 300 shows that field plates 101 of the module are free of corrosion. Residues 301 that may be noticed in view 300 are residues of the very well adhering spin-on silicone passivation (the spin-on silicone passivation was substantially removed from the chips before taking the images shown in FIG. 3).

Various embodiments provide a passivation material or layer with improved moisture stability, which may be due to significantly lower binding of moisture from the environment, in other words significantly lower deliquescence.

Various embodiments provide a passivation material or layer, which may be nearly mechanically stress-free. In accordance with various embodiments, the passivation material may be an organic dielectric material. In accordance with various embodiments, the passivation material may have a water uptake of less than or equal to 0.5 wt % in saturation. In accordance with various embodiments, the passivation material may be a silicone material, e.g. a spin-coatable silicone material (spin-on silicone material), e.g. a spin-coatable and photopatternable silicone material.

Due to the aforementioned material characteristics, a device's resistance against outer impacts such as, e.g., corrosion may be improved significantly. The improved (i.e., reduced) deliquescence may have the effect that less H₂O may be available for a corrosion process.

The reduced mechanical stress may lead to improved adhesion of the passivation (e.g. to an underlying layer, e.g. a metal layer, or an oxide layer, or a semiconductor layer, e.g. a silicon layer) and may prevent delamination of the passivation. Thus, it may be prevented, for example, that H₂O or further moisture films are created between passivation and metal.

In addition to an improved corrosion behavior, a degradation of further passivation layers (if present) may be prevented.

In accordance with some embodiments, it is also possible to not just replace conventionally used passivation materials (e.g. polyimide) by the new passivation material described herein, but use the new passivation material in addition to standard passivations, e.g. above and/or below the standard passivations. In case of a photopatternable passivation material such as photopatternable spin-on silicone, an anti-reflective coating may be provided for photopatterning in accordance with some embodiments when the photopatternable passivation material (e.g. spin-on silicone) is deposited over a reflective material, e.g. a metal such as, e.g., aluminum. The anti-reflective coating may include or may be made of, e.g., silicon nitride (SiₓN_{y}, e.g. Si₃N₄), PVD-Si, silicon oxide (e.g. SiO₂), Ta, Ti, WTi, TiN, TaN, WTiN, or the like, or combinations thereof, although other materials may be possible as well. The anti-reflective coating may, for example, have a layer thickness of several hundred nanometers, e.g. about 800 nm in one or more embodiments, although other thicknesses may be possible as well.

In accordance with some embodiments, a method for processing a power semiconductor device may include, e.g. after forming a frontside metallization and a passivation of the device, depositing a spin-on silicone layer (by means of spin-on deposition (spin coating)), subsequently heating the power semiconductor device at about 100° C. to 120° C., e.g. at about 110° C., for about 120 s (soft bake), subsequently mask exposing with a dose of about 600 mJ to 1200 mJ, e.g. a dose of about 1000 mJ to 1200 mJ, subsequently heating the power semiconductor device at about 120° C. to about 145° C., e.g. at about 140° C., for about 120 s (post exposure bake), subsequently developing, rinsing, and backside cleaning (both with, e.g., butylacetate or other solvents), subsequently heating the power semiconductor device at more than or equal to about 200° C., e.g. at about 250° C., for more than or equal to about 100 min, e.g. for about 120 min, under inert gas atmosphere, e.g. N₂ or H₂N₂ ambient (hard bake), subsequently etching an anti-reflective film. In one or more embodiments, ion implantation (backside implantation)/backside metal deposition, backside metal tempering, and/or other processes may be carried out subsequently.

In accordance with various embodiments, a stress-free or substantially stress-free and lowly hygroscopic chip passivation such as, e.g., spin-coatable and photopatternable spin-on silicone may be used for semiconductor systems, e.g. power semiconductor devices. This passivation (e.g. spin-on silicone) may be characterized by a low uptake/binding of moisture from the environment (deliquescence) and may be free or substantially free from mechanical stress. An effect of using the new passivation may be an increased robustness of power semiconductor devices against environmental impacts such as, e.g., corrosion. Thus, power semiconductor devices or modules in accordance with one or more embodiments may operate more reliably under harsh environmental conditions such as, e.g., heat, high air humidity, air pollution, or the like.

FIG. 4 shows a power semiconductor device 400 in accordance with various embodiments.

The power semiconductor device 400 may include: a semiconductor body 401; and a passivation layer 402 disposed over at least a portion of the semiconductor body 401, wherein the passivation layer 402 includes an organic dielectric material having a water uptake of less than or equal to 0.5 wt % in saturation.

In one or more embodiments, the term “water uptake” may include or may refer to a maximum amount of water or moisture that a material takes up (in other words, absorbs).

In one or more embodiments, the organic dielectric material may have a water uptake of less than or equal to 0.4 wt % in saturation, e.g. less than or equal to 0.3 wt % in one or more embodiments, e.g. about 0.25 wt % in one or more embodiments.

In one or more embodiments, the organic dielectric material may have a breakdown voltage of greater than or equal to 3 MV/cm, e.g. greater than or equal to 3.5 MV/cm in one or more embodiments, e.g. greater than or equal to 4 MV/cm in one or more embodiments, e.g. about 4 MV/cm.

In one or more embodiments, the organic dielectric material may have a tensile strength of less than or equal to 100 MPa, e.g. less than or equal to 50 MPa in one or more embodiments, e.g. less than or equal to 20 MPa in one or more embodiments, e.g. less than or equal to 10 MPa in one or more embodiments, e.g. about 5 MPa in one or more embodiments.

In one or more embodiments, the organic dielectric material may have a Young modulus (sometimes also referred to as tensile modulus or elastic modulus) of less than or equal to 1 GPa, e.g. less than or equal to 500 MPa in one or more embodiments, e.g. less than or equal to 100 MPa in one or more embodiments, e.g. less than or equal to 50 MPa in one or more embodiments, e.g. less than or equal to 20 MPa in one or more embodiments.

In one or more embodiments, the passivation layer 402 may have a thickness of less than or equal to 1 mm, e.g. less than or equal to 500 μm, e.g. less than or equal to 200 μm, e.g. less than or equal to 100 μm, e.g. less than or equal to 50 μm, e.g. less than or equal to 20 μm, e.g. less than or equal to 10 μm, e.g. in the range from 0.1 μm to 200 μm, e.g. in the range from 1 μm to 50 μm, e.g., in the range from 5 μm to 50 μm, e.g. in the range from 5 μm to 20 μm, e.g. in the range from 5 μm to 10 μm, e.g. in the range from 20 μm to 40 μm, e.g. about 40 μm, e.g. about 20 μm, e.g. about 10 μm, e.g. about 5 p.m.

In one or more embodiments, the organic dielectric material may include or may be a silicone material.

In one or more embodiments, the silicone material may include or may be a photopatternable silicone material.

In one or more embodiments, the power semiconductor device 400 may further include an anti-reflective coating between the semiconductor body 401 and the passivation layer 402 (not shown). The anti-reflective coating may, for example, include or be made of one or more of the materials described herein above.

In one or more embodiments, the silicone material may include or may be a thermally curable silicone material.

In one or more embodiments, the silicone material may include or may be a spin-coatable silicone material.

In one or more embodiments, the silicone material may include or may be a silicone material that may be deposited by film lamination, e.g. a silicone foil or film.

In one or more embodiments, the silicone material may include or may be a silicone material that may be deposited by a printing process, e.g. stencil printing, screen printing, inkjet printing, or the like.

In one or more embodiments, the passivation layer 402 may be formed by a method including: depositing a thermally curable silicone material over the semiconductor body 401; thermally curing the thermally curable silicone material in an inert atmosphere having an oxygen level of less than or equal to 1 ppm (parts per million).

In one or more embodiments, the oxygen level may be less than or equal to 500 ppb (parts per billion), e.g. less than or equal to 200 ppb. e.g. less than or equal to 100 ppb, e.g. less than or equal to 50 ppb.

In one or more embodiments, thermally curing the thermally curable silicone material may include: placing the power semiconductor device 400 in a process chamber, while the process chamber is at a first temperature of less than or equal to 120° C.; carrying out a purge with an inert gas; increasing the temperature of the process chamber from the first temperature to a second temperature of about 380° C. at a rate of about 5° C./min; heating the power semiconductor device 400 in the process chamber for about 30 min, while the process chamber is at the second temperature; decreasing the temperature of the process chamber from the second temperature to a third temperature of less than or equal to 120° C. at a rate of about 5° C./min.

In one or more embodiments, the passivation layer 402 may be formed in a front end process.

In one or more embodiments, the power semiconductor device 400 may be configured as a chip.

In one or more embodiments, the power semiconductor device 400 may be configured as a bare die. In one or more embodiments, the term “bare die” may include or refer to a chip that is free from a molding compound. In other words, in one or more embodiments, the power semiconductor device 400 may not contain a molding compound.

In one or more embodiments, the passivation layer 402 may be configured as a chip end passivation layer. In one or more embodiments, the term “chip end passivation layer” may include or refer to a final terminating passivation layer, e.g. a topmost passivation layer, of a chip or die.

In one or more embodiments, the semiconductor body 401 may include or may be made of at least one semiconductor material, e.g. silicon, although other semiconductor materials, including compound semiconductor materials, such as, e.g., germanium, silicon germanium, silicon carbide, indium phosphide, indium gallium arsenide, to name only a few, may be possible as well.

In one or more embodiments, the semiconductor body 401 may include a plurality of layers. In one or more embodiments, the plurality of layers may include at least one semiconducting layer, and/or at least one insulating layer, and/or at least one conductive layer.

In one or more embodiments, the passivation layer 402 may be disposed directly on a semiconductor or semiconductor based surface, e.g. on a silicon or silicon based surface, e.g. a silicon oxide or silicon nitride surface, of the semiconductor body 401.

In one or more embodiments, the power semiconductor device 400 may include or may be a power transistor, e.g. a power IGBT.

In one or more embodiments, the power semiconductor device 400 may include or may be a power diode.

In one or more embodiments, the power semiconductor device 400 may include or may be a high-voltage device.

FIG. 5 shows another power semiconductor device 500 in accordance with various embodiments.

The semiconductor device 500 may be to some degree similar to semiconductor device 400. In particular, reference signs that are the same as in FIG. 4 may denote the same or similar elements as in FIG. 4. The semiconductor device 500 may include at least one structure to be protected. The passivation layer 402 may be disposed over the at least one structure to be protected.

For example, in one or more embodiments, the semiconductor device 500 may include a first structure 403a to be protected and a second structure 403b to be protected, as shown in FIG. 5. In other embodiments, the semiconductor device 500 may include only one structure to be protected, e.g. the first structure 403a or the second structure 403b or another structure. In still other embodiments, the semiconductor device 500 may include three or more structures to be protected.

In one or more embodiments, the at least one structure may be disposed in or on the semiconductor body 401.

In one or more embodiments, the at least one structure may be disposed at a surface of the semiconductor body 401.

In one or more embodiments, the at least one structure (e.g. the first structure 403a) may be disposed at a boundary area of the semiconductor body 401. In one or more embodiments, the boundary area of the semiconductor body 401 may correspond to a boundary of a chip. In one or more embodiments, the boundary area may be an area where high electric fields may occur and/or where high electric fields may be reduced. Due to the occurrence of high electric fields this area may be particularly prone to corrosion. Thus, it may be desirable to prevent moisture or corrosion-promoting ions from entering this area.

In one or more embodiments, the at least one structure (e.g. the first structure 403a) may include or may be a guard ring.

In one or more embodiments, the at least one structure (e.g. the first structure 403a) may include a plurality of guard rings.

In one or more embodiments, the at least one structure (e.g. the first structure 403a) may include or may be a field plate.

In one or more embodiments, the at least one structure (e.g. the first structure 403a) may include a plurality of field plates.

In one or more embodiments, the power semiconductor device 500 may include an active region. In one or more embodiments, the active region may include an electrical contact 404. In one or more embodiments, the electrical contact 404 may be an emitter contact of an IGBT. In one or more embodiments, the emitter contact 404 may include or may be a pad, e.g. metal pad, configured for bonding. In one or more embodiments, a bonding structure 405, e.g. a bonding wire, may be bonded to the pad 404.

In one or more embodiments, the at least one structure (e.g. the second structure 403b) may include or may be an electrical contact of the power semiconductor device 500. In one or more embodiments, the electrical contact may be a gate contact of an IGBT. In one or more embodiments, the passivation layer 402 may be disposed over the gate contact and may prevent the gate and emitter contacts of the IGBT from being shorted.

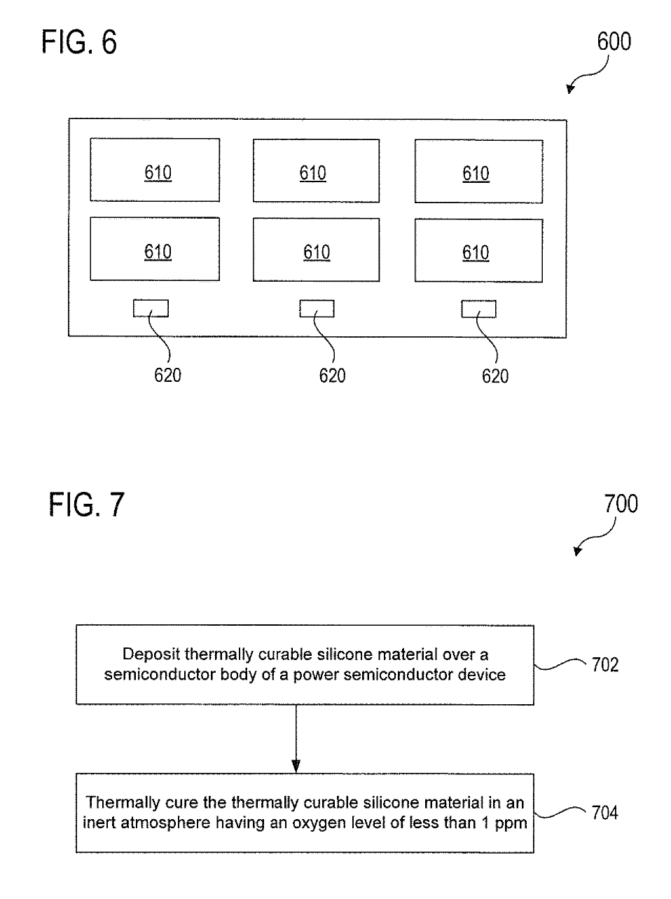

FIG. 6 shows, as a plan view, a power electronic module 600 in accordance with various embodiments.

The power electronic module 600 may include: a plurality of power semiconductor devices 610, each including a semiconductor body and a passivation layer disposed over at least a portion of the semiconductor body, wherein the passivation layer includes an organic dielectric material having a water uptake of less than or equal to 0.5 wt % in saturation; and at least one contact 620 connected to the plurality of power semiconductor devices.

In one or more embodiments, the passivation layer may include or may be a silicone material.

In one or more embodiments, the passivation layer may have a thickness of less than or equal to 1 mm.

In one or more embodiments, each of the power semiconductor devices 610 may include or may be a bare die.

In one or more embodiments, the power semiconductor devices 610 may be electrically connected to one another.

In one or more embodiments, the power electronic module 600 may be configured as a high-voltage module.

In one or more embodiments, the power electronic module 600 may be configured as an IGBT module.

In one or more embodiments, the power electronic module 600 may be configured as a diode module.

In one or more embodiments, the power electronic module 600 may be configured to operate with voltages in the kV (kilovolts) regime, e.g. voltages of several kilovolts, e.g. voltages of up to about 6.5 kV in one or more embodiments, e.g. voltages from about 3 kV to 6 kV in one or more embodiments, although other voltages or voltage ranges may be possible as well in accordance with other embodiments.

In one or more embodiments, the power electronic module 600 may be configured to operate with currents of up to several hundred amperes, e.g. currents of up to about 200 A in one or more embodiments, or up to about 400 A in one or more embodiments, or up to about 600 A in or more embodiments, although other currents or current ranges may be possible as well in accordance with other embodiments.

One or more, e.g. all, of the power semiconductor devices 610 may further be configured in accordance with one or more embodiments described herein, e.g. one or more embodiments described in connection with FIG. 4 and/or FIG. 5.

The number of power semiconductor device 610 in the power electronic module 600 may vary according to the specific application. For example, six power semiconductor devices 610 are shown as an example in FIG. 6, however the number may not be limited to six and may e.g. be 4, 8, 16, 24, 32, or 36, to name only a few other examples.

The at least one contact 620 may be configured to electrically contact the power semiconductor devices 610.

In one or more embodiments, the power electronic module 600 may include a plurality of contacts 620 connected to the power semiconductor devices 610. For example, in an example, the number of contacts 620 may be three, as shown in FIG. 6, however according to other embodiments, the number of contacts 620 may be different from three. The number of contacts 620 may vary according to the specific application.

In one or more embodiments, the power electronic module may include a layer of silicone gel that may cover the plurality of power semiconductor devices 610 (e.g. chips) and the at least one contact 620 (or plurality of contacts 620).

In one or more embodiments, the layer of silicone gel may have a thickness of greater or equal to 5 mm, e.g. greater or equal to 1 cm.

In one or more embodiments, a plurality of power electronic modules (e.g. IGBT modules and/or diode modules) may be assembled to a power electronic building block. Each of the power electronic modules may be configured in accordance with one or more embodiments described herein. In one or more embodiments, a plurality of power electronic building blocks may be assembled to a high-voltage converter.

FIG. 7 shows a method 700 for processing a power semiconductor device in accordance with various embodiments.

Method 700 may include: depositing a thermally curable silicone material over a semiconductor body of a power semiconductor device (in 702); and thermally curing the thermally curable silicone material in an inert atmosphere having an oxygen level of less than or equal to 1 ppm (in 704).

In one or more embodiments, the power semiconductor device may include a power transistor, e.g. an IGBT.

In one or more embodiments, the power semiconductor device may include a diode.

In one or more embodiments, the oxygen level may be less than or equal to 500 ppb (parts per billion), e.g. less than or equal to 200 ppb. e.g. less than or equal to 100 ppb, e.g. less than or equal to 50 ppb.

In one or more embodiments, depositing the silicone material over the semiconductor body may include or may be effected by a spin-coating process.

In one or more embodiments, depositing the silicone material over the semiconductor body may include or may be effected by a film lamination process.

In one or more embodiments, depositing the silicone material over the semiconductor body may include or may be effected by a printing process, e.g. a stencil printing process, a screen printing process, an inkjet printing process, or the like.

In one or more embodiments, method 700 may further include patterning the silicone material to form a mask, and etching at least one underlying layer of the power semiconductor device using the mask. In other words, the patterned silicone material may be used as an etch mask while etching at least one layer exposed by the patterned silicone material.

In one or more embodiments, the at least one underlying layer may include or may be an anti-reflective coating.

In one or more embodiments, etching the at least one underlying layer may include a dry etch process, e.g. a plasma chemical etch process, or a wet chemical etch process. A plasma chemical etch process may use, e.g., SF₆, BCl₃, Cl₂, and/or CF₄ as an etch gas, although other etch gases may be possible as well.

In one or more embodiments, patterning the silicone material and etching the at least one underlying layer may be carried out before thermally curing the silicone material.

In one or more embodiments, thermally curing the thermally curable silicone material may include: placing the power semiconductor device in a process chamber, while the process chamber is at a first temperature; increasing the temperature of the process chamber from the first temperature to a second temperature; heating the power semiconductor device in the process chamber for a predeterminable time period, while the process chamber is at the second temperature; decreasing the temperature of the process chamber from the second temperature to a third temperature; removing the power semiconductor device from the process chamber after the process chamber has reached the third temperature.

In one or more embodiments, the first temperature may be less than or equal to 120° C., the second temperature may be in the range from about 250° C. to about 400° C., and the third temperature may be less than or equal to 120° C.

In one or more embodiments, at least one of increasing the temperature of the process chamber from the first temperature to the second temperature or decreasing the temperature of the process chamber from the second temperature to the third temperature may include changing the temperature of the process chamber at a rate of about 4° C./min to 6° C./min, e.g. at a rate of about 5° C./min.

In one or more embodiments, the predeterminable time period may be in the range from about 30 min to about 120 min.

In one or more embodiments, the first temperature may be less than or equal to 120° C., increasing the temperature of the process chamber from the first temperature to the second temperature may include changing the temperature at a rate of about 5° C./min; the second temperature may be about 380° C., the predeterminable time period may be about 30 min, decreasing the temperature of the process chamber from the second temperature to the third temperature may include changing the temperature at a rate of about 5° C./min; and the third temperature may be less than or equal to 120° C.

In one or more embodiments, method 700 may further include carrying out a purge with an inert gas after placing the power semiconductor device in the process chamber and before increasing the temperature of the process chamber.

In one or more embodiments, the inert gas may include or may be nitrogen.

In one or more embodiments, method 700 may further include depositing an anti-reflective coating over the semiconductor body before depositing the silicone material. The silicone material may be deposited on the anti-reflective coating. The anti-reflective coating may include or may be made of one or materials described herein above.

Various embodiments may provide a reliable chip end passivation layer for semiconductor devices (e.g. power semiconductor devices, e.g. IGBTs or power diodes) that may need to be operated under harsh environmental conditions such as high temperature, high air humidity, air pollution. Long-term stress tests (e.g. HV-H3TRB) at modules including chips having the chip end passivation layer have shown that, e.g., corrosion may be prevented, as shown e.g. in FIG. 3.

While various aspects of this disclosure have been particularly shown and described with reference to specific embodiments, it should be understood by those skilled in the art that various changes in form and detail may be made therein without departing from the spirit and scope of the disclosure as defined by the appended claims. The scope of the disclosure is thus indicated by the appended claims and all changes which come within the meaning and range of equivalency of the claims are therefore intended to be embraced.

What is claimed is:

1. A power semiconductor device, comprising:
a semiconductor body;
a passivation layer disposed over at least a portion of the semiconductor body, wherein the passivation layer comprises an organic dielectric material having a water uptake of less than or equal to 0.5 wt % in saturation.

2. The power semiconductor device of claim 1, wherein the organic dielectric material has a breakdown voltage of greater than or equal to 3 MV/cm.

3. The power semiconductor device of claim 1, wherein the organic dielectric material has a tensile strength of less than or equal to 100 MPa.

4. The power semiconductor device of claim 1, wherein the organic dielectric material has a Young modulus of less than or equal to 1 GPa.

5. The power semiconductor device of claim 1, wherein the passivation layer has a thickness of less than or equal to 1 mm.

6. The power semiconductor device of claim 1, wherein the organic dielectric material comprises a silicone material.

7. The power semiconductor device of claim 6, wherein the silicone material comprises a photopatternable silicone material.

8. The power semiconductor device of claim 6, wherein the silicone material comprises a thermally curable silicone material.

9. The power semiconductor device of claim 6, wherein the silicone material comprises at least one of a spin-coatable silicone material, a laminatable silicone material, and a printable silicone material.

10. The power semiconductor device of claim 1, wherein the passivation layer is disposed over a structure disposed at a boundary area of the semiconductor body.

11. The power semiconductor device of claim 10, wherein the structure comprises at least one of a guard ring and a field plate.

12. The power semiconductor device of claim 1, configured as a bare die.

13. A power electronic module, comprising:
a plurality of power semiconductor devices, each comprising a semiconductor body and a passivation layer disposed over at least a portion of the semiconductor body, wherein the passivation layer comprises an organic dielectric material having a water uptake of less than or equal to 0.5 wt % in saturation; and
at least one contact connected to the plurality of power semiconductor devices.

14. The power electronic module of claim 13, wherein the passivation layer comprises a silicone material.

15. The power electronic module of claim 13, wherein the passivation layer has a thickness of less than or equal to 1 mm.

16. The power electronic module of claim 13, wherein each of the power semiconductor devices is configured as a bare die.

17. A method for processing a power semiconductor device, comprising:
depositing a thermally curable silicone material over a semiconductor body of a power semiconductor device;
thermally curing the thermally curable silicone material in an inert atmosphere having an oxygen level of less than or equal to 1 ppm.

18. The method of claim 17, wherein depositing the silicone material over the semiconductor body comprises at least one of a spin-coating process, a lamination process, and a printing process.

19. The method of claim 17, further comprising patterning the silicone material to form a mask, and etching at least one underlying layer of the power semiconductor device using the mask.

20. The method of claim 17, wherein thermally curing the thermally curable silicone material comprises:
placing the power semiconductor device in a process chamber, while the process temperature is at a first temperature;
increasing the temperature of the process chamber from the first temperature to a second temperature;
heating the power semiconductor device in the process chamber for a predeterminable time period, while the process chamber is at the second temperature;
decreasing the temperature of the process chamber from the second temperature to a third temperature;
removing the power semiconductor device from the process chamber after the process chamber has reached the third temperature.

21. The method of claim 20, wherein the first temperature is less than or equal to 120° C., wherein the second temperature is in the range from about 250° C. to about 400° C., and wherein the third temperature is less than or equal to 120° C.

22. The method of claim 20, wherein at least one of increasing the temperature of the process chamber from the first temperature to the second temperature or decreasing the temperature of the process chamber from the second temperature to the third temperature comprises changing the temperature of the process chamber at a rate of about 5° C./min.

23. The method of claim 20, wherein the predeterminable time period is in the range from about 30 min to about 120 min.

24. The method of claim 20,
wherein the first temperature is less than or equal to 120° C.;
wherein increasing the temperature of the process chamber from the first temperature to the second temperature comprises changing the temperature at a rate of about 5° C./min;
wherein the second temperature is about 380° C.;
wherein the predeterminable time period is about 30 min;
wherein decreasing the temperature of the process chamber from the second temperature to the third temperature comprises changing the temperature at a rate of about 5° C./min; and
wherein the third temperature is less than or equal to 120° C.

25. The method of claim 20, further comprising carrying out a purge with an inert gas after placing the power semiconductor device in the process chamber and before increasing the temperature of the process chamber.
